(19) United States
(12) Patent Application Publication
(10) Pub. No.: US 2014/0201986 A1
(43) Pub. Date: Jul. 24, 2014

(54) Auxiliary Device for Sticking a Film on a Portable Electronic Product

(71) Applicant: Pei Fong Lo, New Taipei City (TW)

(72) Inventor: Pei Fong Lo, New Taipei City (TW)

(21) Appl. No.: 13/746,287

(22) Filed: Jan. 21, 2013

(51) Int. Cl. H05K 13/00

(52) U.S. Cl. CPC H05K 13/00
USPC 29/729

(57) ABSTRACT

An auxiliary device to stick a film on a portable electronic product includes a holding base having plural sets of positioning holes and an auxiliary cover having one set of positioning posts. The positioning posts are inserted in the positioning holes to assemble the auxiliary cover and the holding base together and to tightly wrap the portable electronic product therein. The auxiliary cover has a limit frame which has four sides to form a hollow area within the limit frame. The hollow area corresponds to the screen or the rear cover of the portable electronic product. Through the present invention, a protective film can be stuck on the electronic product accurately, quickly and flat, without bubbles or wrinkles. By the same holding base to cooperate with different auxiliary covers, the present invention is adapted for electronic products in different sizes to save the cost and to enhance its convenience.

### NOTICE OF COPYRIGHT

A portion of the disclosure of this patent document contains material which is subject to copyright protection. The copyright owner has no objection to any reproduction by anyone of the patent disclosure, as it appears in the United States Patent and Trademark Office patent files or records, but otherwise reserves all copyright rights whatsoever.

### BACKGROUND OF THE PRESENT INVENTION

1. Field of Invention

The present invention relates to an auxiliary device to stick a film on a portable electronic product, and more particularly to an auxiliary device for a user to stick a protective film on the screen or the rear cover of the electronic product accurately and quickly. When the user purchases a new electronic product, it is not necessary to discard the existing auxiliary device. Only the auxiliary cover has to be replaced. The present invention can be applied to different electronic products.

2. Description of Related Arts

The front or the rear of a portable electronic product, such as a smart phone, a tablet computer or the like, has a large-sized screen or a high-class casing. In order to prevent the electronic product from being rubbed or damaged, a protective film is stuck on the surface the electronic product. However, it is difficult to stick the protective film accurately. The protective film must be stuck on the electronic product in seconds. When a release film is torn from the protective film, it will generate static electricity to attract the surrounding dust particles. During film sticking process, the dust particles will form air bubbles which are not easy to be removed. Besides, the protective film must be stuck from one end aimed at one side of the electronic product. It is not easy to know when the protective film is not aimed during the process. At the end of the process, it will be too late for the user to find the protective film doesn't be stuck accurately. This may influence the function and appearance of the electronic product. There are various electronic products on the market, and they don't have a uniform specification. Accordingly, the inventor of the present invention has devoted himself based on his many years of practical experiences to develop an auxiliary device to stick a film so as to avoid a waste of sources and to save the cost.

### SUMMARY OF THE PRESENT INVENTION

The primary object of the present invention is to provide an auxiliary device to stick a film on a portable electronic product. The auxiliary device comprises a holding base and an auxiliary cover which are assembled together. The auxiliary cover conforms to the size of the electronic product to wrap and couple the electronic product on the holding base. The auxiliary cover has a limit frame. The limit frame has a hollow area to form a position for sticking the film on the electronic product. The holding base has plural sets of positioning holes, and the auxiliary cover has one set of positioning posts. The positioning posts are inserted in one set of the positioning holes so that the auxiliary cover is coupled on the holding base firm. The protective film can be stuck on the electronic product quickly and accurately.

A further object of the present invention is to provide an auxiliary device to stick a film on a portable electronic product, wherein the holding base has plurality sets of positioning holes for insertion of the positioning posts of the auxiliary cover which can be in different sizes. By replacing with different auxiliary covers, the present invention can be applied to different electronic products to avoid a waste of sources and to save the cost.

### BRIEF DESCRIPTION OF THE DRAWINGS

FIG. 1 is an exploded view of the present invention and an electronic product;

FIG. 2 is a perspective view of the present invention to assist in sticking a film;

FIG. 3 is a sectional view of the present invention to assist in sticking a film;

FIG. 4 is an exploded view of another auxiliary cover of the present invention and an electronic product;

FIG. 5 is a perspective view of an embodiment of the auxiliary cover the present invention; and

FIG. 6 is a perspective view of an embodiment of the positioning holes the present invention.

### DETAILED DESCRIPTION OF THE PREFERRED EMBODIMENT

Embodiments of the present invention will now be described, by way of example only, with reference to the accompanying drawings.

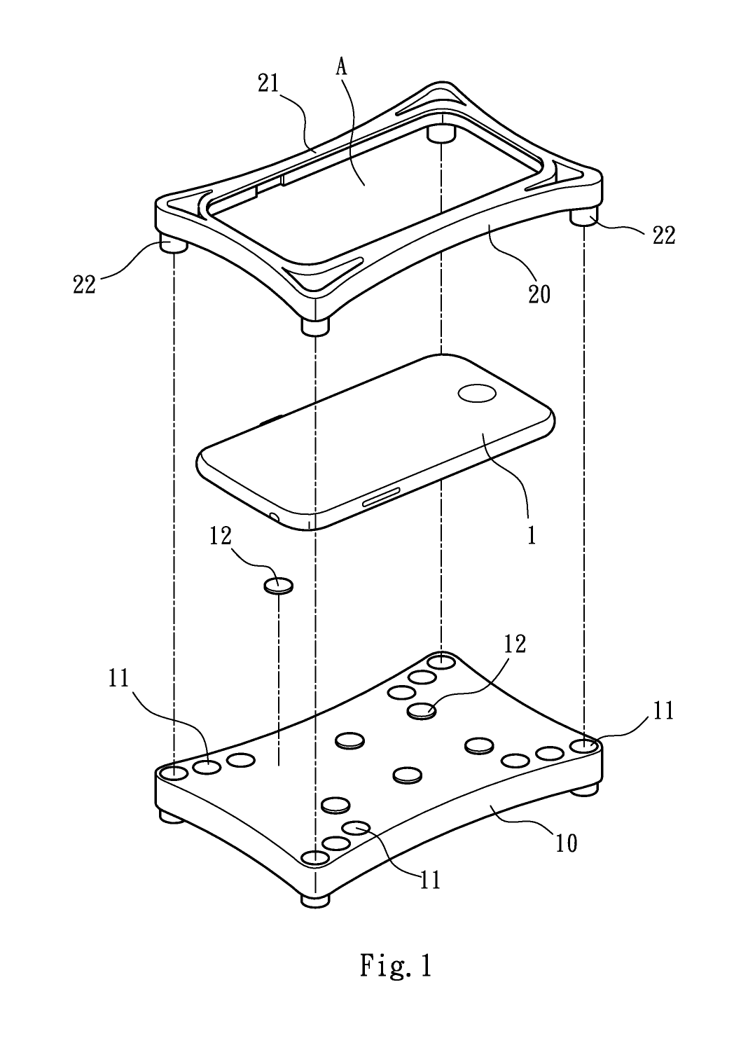

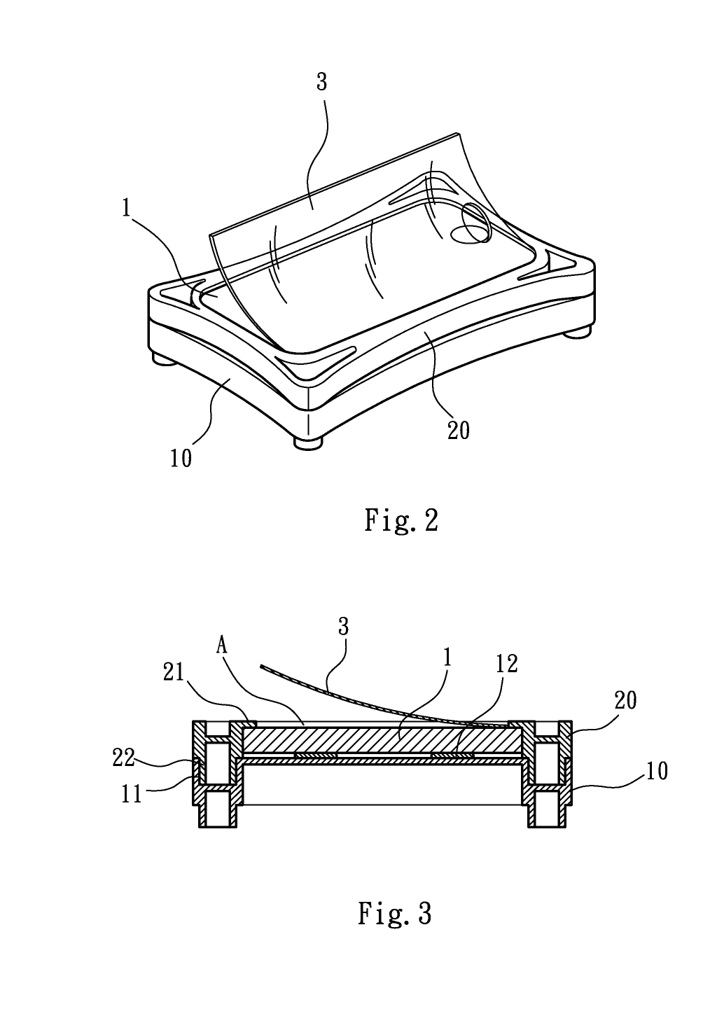

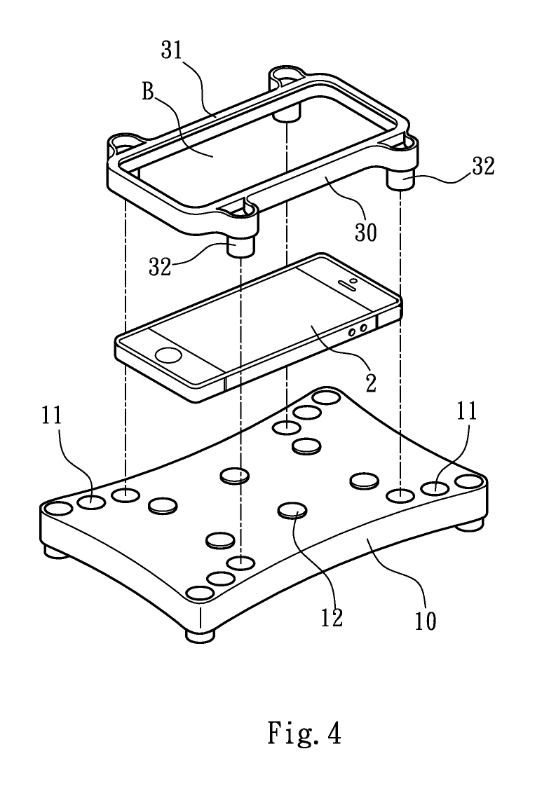

As shown in FIG. 1, FIG. 2 and FIG. 3, the auxiliary device of the present invention is made of a hard plastic material, and comprises a holding base 10 and an auxiliary cover 20 to be assembled together. The holding base 10 has plural sets of positioning holes 11 at four corners thereof. The symmetrical positioning holes 11 at the four corners of the holding base 10 are defined as one set of positioning holes. The holding base 10 further comprises a plurality of plastic pads 12 which are evenly arranged on the holding base 10. The auxiliary cover 20 has a limit frame 21 and four positioning posts 22 at four corners thereof. The positioning posts 22 correspond to one set of the positioning holes 11 of the holding base 10 to assemble an electronic product therein. After the holding base 10 and the auxiliary cover 20 are assembled, the inner space therebetween conforms to the size of the electronic product 1 so as to tightly accommodate the electronic product therein. The plastic pads 12 can prevent the casing or the screen of the electronic product 1 from being rubbed and damaged by the holding base 10. The limit frame 21 of the auxiliary cover 20 has four sides to form a hollow area A within the limit frame 21. The hollow area A corresponds to the screen or the rear cover of the portable electronic product 1 as well as the size of a protective film 3 sold on the market. When in use, as shown in FIG. 2, the inner edge of the limit frame 21 is as a datum (reference), so that the protective film 3 can be positioned quickly and accurately to be stuck on the electronic product 1. When a different electronic product 2 is replaced, as shown in FIG. 4, only a corresponding auxiliary cover 30 is required. The auxiliary cover 30 has a limit frame 31 and positioning posts 32 at four corners thereof. The positioning posts 32 are inserted into another set of the positioning holes 11. A hollow area B defined within the limit frame 31 of the auxiliary cover 30 is the position to stick a protective film. Therefore, it is only necessary to change a corresponding auxiliary cover 30 when a different electronic apparatus is replaced, without discarding the whole film sticking device, so as to avoid a waste of resources.

According to the aforesaid, the present invention has the following effects and advantages:

1. The present invention can assist the user in sticking the protective film quickly, accurately and flat

2. By using the same holding base 10 and different auxiliary covers, the present invention can be applied to different electronic products for sticking a film, which can decrease the waste and avoid pollution of the environment and a waste of sources so the present invention is convenient and practical.

3. Only the auxiliary cover is required for replacement. The present invention can be applied to different electronic products for sticking a film. For consumers, if the periphery products can be reused, the cost can be lowered when purchasing a new electronic product. For producers, the mold cost can be saved by using the same holding base 10.

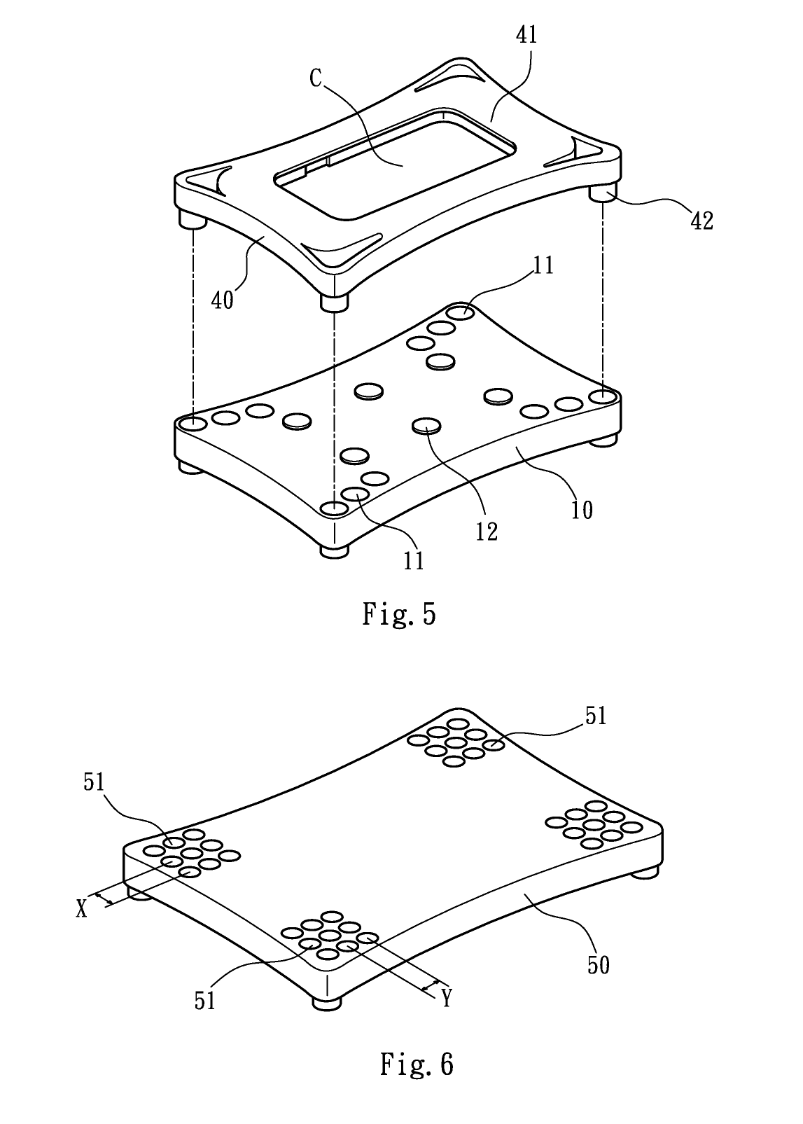

FIG. 5 shows another embodiment of the auxiliary cover 40. The auxiliary cover 40 has a limit frame 41. The hollow area C defined within in the limit frame 41 can be changed. The size of the hollow area C is adapted for different electronic products. In other words, the position of the positioning posts 42 is not changed, only the size of the limit frame 41 is changed to achieve the same effect. As shown in FIG. 6, the positioning holes 51 at the four corners of the holding base 50 are arranged in the form of a lattice. The horizontal distance X and the vertical distance Y between adjacent positioning holes 51 are the same. The auxiliary cover can be designed to conform to the position the positioning holes.

Although particular embodiments of the present invention have been described in detail for purposes of illustration, various modifications and enhancements may be made without departing from the spirit and scope of the present invention. Accordingly, the present invention is not to be limited except as by the appended claims.

What is claimed is:

1. An auxiliary device to stick a film on a portable electronic product, comprising a holding base and an auxiliary cover, the holding base having plural sets of positioning holes at four corners thereof, the auxiliary cover having a limit frame and four positioning posts at four corners thereof, the positioning posts corresponding to one set of the positioning holes of the holding base to assemble the auxiliary cover and the holding base together, the limit frame having four sides to form a hollow area within the limit frame, and the hollow area of the limit frame forming a film sticking position.

2. The auxiliary device as claimed in claim 1, wherein the holding base further comprises a plurality of plastic pads which are evenly arranged on the holding base.

3. The auxiliary device as claimed in claim 1, wherein the positioning holes are arranged in the form of a lattice.
